(19) United States
(12) Patent Application Publication
(10) Pub. No.: US 2019/0074343 A1
(43) Pub. Date: Mar. 7, 2019

(54) FMM PROCESS FOR HIGH RES FMM

(71) Applicant: Applied Materials, Inc., Santa Clara, CA (US)

(72) Inventor: Dieter HAAS, San Jose, CA (US)

(21) Appl. No.: 16/059,995

(22) Filed: Aug. 9, 2018

Related U.S. Application Data
(60) Provisional application No. 62/553,950, filed on Sep. 4, 2017.

(51) Int. Cl. H01L 27/32; H01L 51/56; H01L 51/00

(52) U.S. Cl. CPC H01L 27/3272; H01L 51/0023; H01L 51/56

(57) ABSTRACT

Aspects disclosed herein relate to apparatus having a combined common metal mask (CMM) and fine metal mask (FMM) used in the manufacture of organic light emitting diodes (OLEDs) and manufacturing methods thereof. In one aspect, a mask assembly is provided. The mask includes a common metal mask having one or more windows therethrough and at least one fine metal mask disposed within the at least one window. In another aspect, a distortion compensation master is disclosed. The mask includes a plurality of windows formed through the mask, the positions of the windows being located to compensate for any distortion, including positional distortion resulting from gravity. As one example, the windows may be positioned higher at or near the center of the mask and decreasingly lower near the edge of the mask.

### CROSS-REFERENCE TO RELATED APPLICATIONS

This application claims benefit of U.S. Provisional Patent Application Ser. No. 62/553,950, filed on Sep. 4, 2017, which is herein incorporated by reference in its entirety.

### BACKGROUND

### Field

Aspects disclosed herein relate to formation of electronic devices on substrates. More particularly, aspects disclosed herein relate to a method and apparatus having a combined common metal mask (CMM) and fine metal mask (FMM) used in the manufacture of organic light emitting diodes (OLEDs).

### Description of the Related Art

OLEDs have recently been used in the manufacture of flat panel displays for television screens, cell phone displays, computer monitors and the like. OLEDs are a type of light-emitting diodes in which a light-emissive layer comprises a plurality of thin films made of certain organic compounds. The range of colors, brightness, and viewing angle possible with OLED displays are greater than those of conventional displays because OLED pixels emit light directly and do not require a back light. Additionally, the energy consumption of OLED displays is considerably less than that of traditional displays.

Current OLED manufacturing methods and apparatus generally use evaporation of organic materials and deposition of metals on a substrate using a plurality of patterned shadow masks. In vertical deposition systems, current shadow masks experience sagging under gravitational force, which is challenging to the alignment and position of the mask over the substrate. Further, it is difficult to achieve full contact with current masks due to a thick backbone of the masks. Additionally, current manufacturing methods and apparatus suffer from alignment issues due to subsequent masking operations.

Therefore, there is a need in the art for improved methods and apparatus for manufacturing OLEDs.

### SUMMARY

Aspects disclosed herein relate to apparatus having a combined common metal mask (CMM) and fine metal mask (FMM) used in the manufacture of organic light emitting diodes (OLEDs) and manufacturing methods thereof. In one aspect, a mask assembly is provided. The mask includes a common metal mask having one or more windows therethrough and at least one fine metal mask disposed within the at least one window. In another aspect, a distortion compensation master is disclosed. The master includes a plurality of windows formed through the mask, the positions of the windows being located to compensate for any distortion, including positional distortion resulting from gravity. As one example, the windows may be positioned higher at or near the center of the mask and decreasingly lower near the edge of the mask.

In one aspect, a mask assembly is disclosed. The mask includes a common metal mask having at least one window therethrough and a fine metal mask disposed within the at least one window.

In another aspect, a mask assembly is disclosed. The mask includes a common metal mask portion having a plurality of windows formed therethrough and a plurality of fine metal mask portions disposed within the plurality of windows of the common metal mask portion.

In yet another aspect, a method of manufacturing a mask assembly is disclosed. The method includes manufacturing a common metal mask having a plurality of windows therein, forming a fine metal mask, comprising, forming a distortion mask having a plurality of distortion compensation windows formed through the distortion mask, the positions of the distortion compensation windows being located higher at or near a center of the distortion mask and decreasingly lower near an edge of the distortion mask, and forming a fine metal mask pattern within each of the distortion compensation windows, and combining the common metal mask and the fine metal mask such that the fine metal mask patterns are disposed in the windows of the common metal mask.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of its scope. The present disclosure may admit to other equally effective aspects.

FIG. 1 is a process flow for manufacturing a mask assembly used for manufacturing OLEDs.

FIGS. 2A-2H depict schematic plan top-down views of a mask assembly for high resolution fine metal masks.

FIG. 3 schematically depicts one aspect of an apparatus for forming an OLED device on a substrate.

To facilitate understanding, identical reference numerals have been used, where possible, to designate identical elements that are common to the figures. It is contemplated that elements and features of one aspect may be beneficially incorporated in other aspects without further recitation.

### DETAILED DESCRIPTION

Aspects disclosed herein relate to apparatus having a combined common metal mask (CMM) and fine metal mask (FMM) used in the manufacture of organic light emitting diodes (OLEDs) and manufacturing methods thereof. In one aspect, a mask assembly is provided. The mask includes a CMM having one or more windows therethrough and at least one FMM disposed within the at least one window. In another aspect, a distortion compensation master is disclosed. The master includes a plurality of windows formed through the master, the positions of the windows being located to compensate for any distortion, including positional distortion resulting from gravity. As one example, the windows may be positioned higher at or near the center of the mask and decreasingly lower near the edge of the mask.

Aspects disclosed herein may be used in a vacuum evaporation or deposition process where multiple layers of thin films are deposited on a substrate, such as a display substrate. For example, the thin films may form a portion of a display on displays on a substrate comprising a plurality of OLEDs performed and used in chambers and systems, such as vertical processing Moreover, aspects disclosed herein may be used in various chambers and systems, including but not limited to vertical processing chambers and systems available from AKT, Inc., a division of Applied Materials, Inc., of Santa Clara Calif.

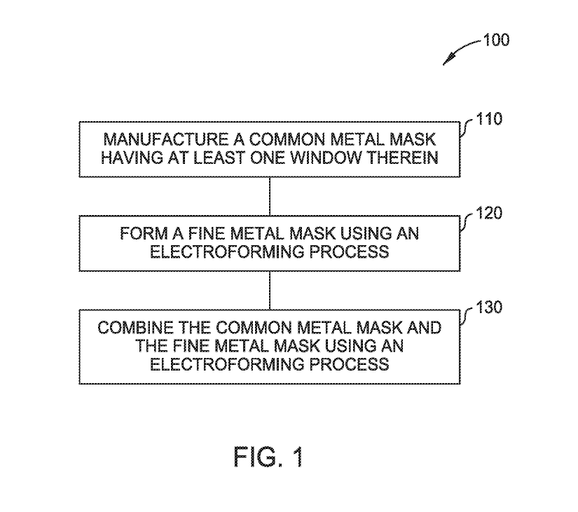

FIG. 1 is a process flow 100 for manufacturing a mask assembly used for manufacturing OLEDs. Process flow 100 begins at operation 110 with manufacturing a CMM. At operation 120, an FMM is formed. At operation 130, the FMM is combined with the CMM, for example, by an electroforming process to form a combined mask assembly having a CMM and an FMM for manufacturing OLEDs.

Operations 110 and 120 may be performed simultaneously or in any suitable sequence. The CMM is generally manufactured by any suitable process, such as etching or cutting windows through a sheet of metal material. Forming the FMM generally includes using one or more lithography processes to form a distortion compensation master to compensate for later sagging due to gravity during vertical processing, and then using single or double electroforming processes to form the FMM, as described below. Electroforming is a process by which metal ions are transferred electrochemically from an anode to a desired surface, through an electrolyte, where they are deposited as atoms of plated metal. The desired surface for deposition is generally conditioned such that the plating does not adhere to the surface, but is slightly separated from the surface such that the plating retains its as deposited shape as a separate component. In one aspect, the FMM is electroformed and then a second electroforming process is used to join the FMM to the CMM. The second electroforming process provides plating between the FMM and the CMM.

Process flow 100 may further include using one or more standard lithography processes to cover at least a portion of the FMM, for example, to protect at least the portion of the FMM during additional processing operations.

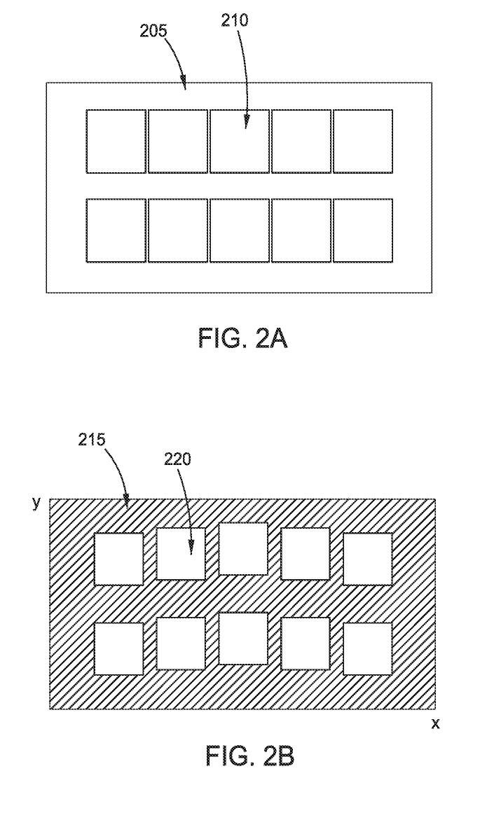

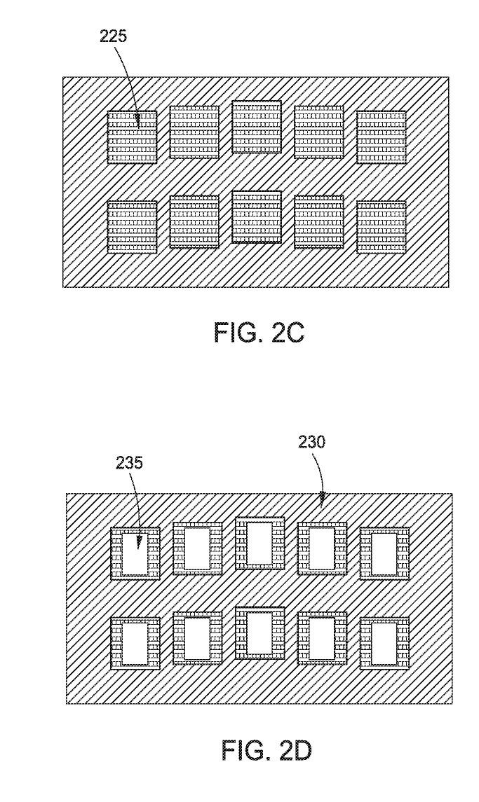

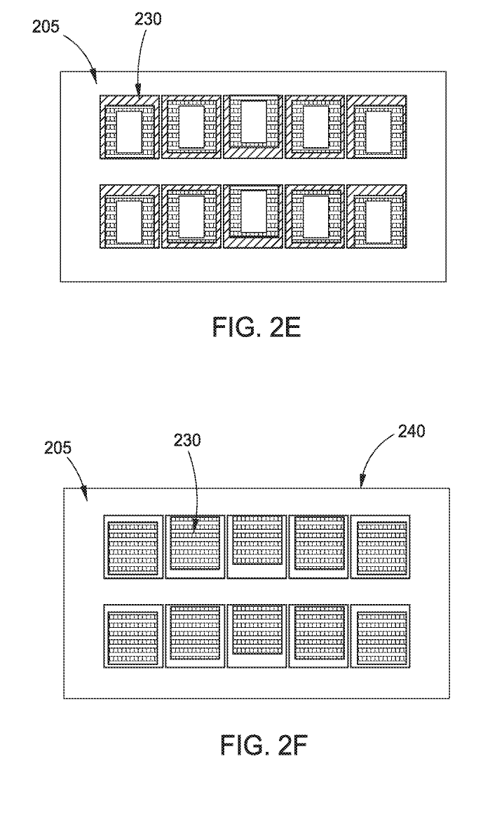

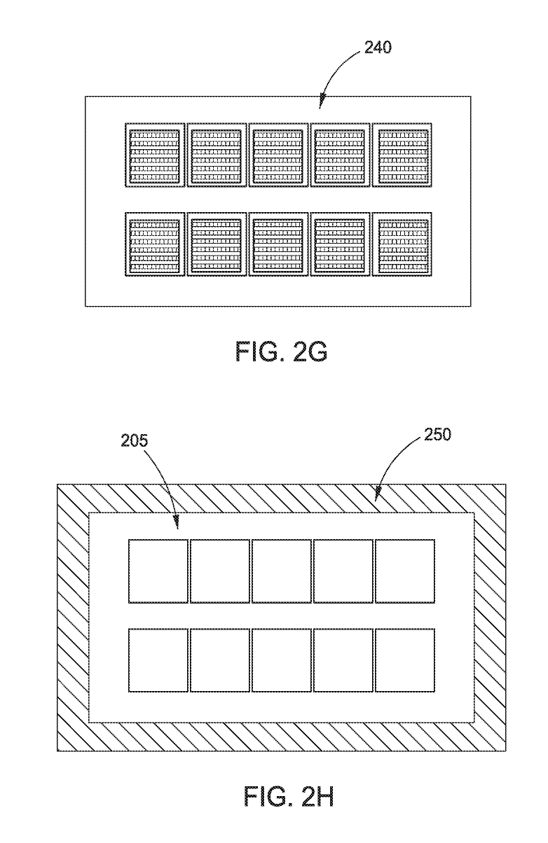

FIGS. 2A-2H depict schematic plan top-down views of a combined mask assembly 240 for high resolution FMMs at various stages of a process flow, such as process flow 100.

As shown in FIG. 2A, a CMM 205 is a sheet of suitable masking material, such as a metal material, for example an INVAR® (Fe:Ni 36) material, and includes at least one window 210 (ten are shown as an example) therethrough. The at least one window 210 has any dimensions suitable for the device to be formed therein. Generally, the at least one window is at least 500 microns (μn) larger than the device to be formed therein.

The CMM 205 is generally coupled to a frame 250, as shown in FIG. 2H prior to, during, or after the process flow, such as the process flow 100. The frame 250 is generally manufactured from a sturdy metal material, which provides increased stability for the CMM 205 during processing. In one aspect, the CMM 205 is welded to the frame 250 under tension, for example, by manually stretching the CMM 205 from all four corners and welding the CMM 205 to the frame 250 while it is under tension. Coupling the CMM 205 to the frame 250 under tension increases the likelihood of maintaining full contact between the CMM 205 and the frame 250 during processing. More particularly, when the temperature inside a process chamber increases during processing, the size and shape of the CMM 205 may change, but because of tensioning, any bubbles or ripples in the CMM 205 will be reduced or eliminated.

FIGS. 2B-2D depict formation of an FMM 230 at various stages of a formation process. As shown in FIG. 2B, a distortion compensation master 215 is formed, for example, by one or more standard lithography processes. The distortion compensation master 215 is formed of any suitable material, including but not limited to, a thin sheet of glass or metal, and ultimately serves as a carrier for FMM patterns to be formed therein. The distortion compensation master 215 is coated with photoresist and patterned such that the distortion compensation master 215 includes at least one distortion compensation window 220 (ten are shown as an example). The distortion compensation windows 220 correspond to the areas of the distortion compensation master 215 that are not coated with photoresist. As shown in the example of FIG. 2B, the distortion compensation windows 220 are formed in two rows. The distortion compensation windows 220 near the center of the distortion compensation master 215 along the horizontal (x) axis are higher relative to the other windows in their respective rows. Furthermore, the height of the distortion compensation windows 220 along the vertical (y) axis generally decreases from the center of the of the distortion compensation master 215 to the edges of the distortion compensation master 215, which provides compensation for sagging (or bending) as a result of gravity during vertical processing, which is generally most significant at or near the center of the substrate, or the distortion compensation master 215.

An FMM pattern 225 is then formed in the distortion compensation windows 220, as shown in FIG. 2C. Forming the FMM pattern 225 generally includes a single or double electroforming process. In one aspect, an electroforming process includes forming a first metal layer on a mandrel by placing the mask pattern into an electrolytic bath, which includes a first metal dissolved therein that becomes the first metal layer, and then forming a second metal layer on the first metal layer by placing the mask pattern into a second electrolytic bath having a second metal dissolved therein that becomes the second metal layer. More specifically, an electrical bias is provided between the mandrel and the first metal in the electrolytic bath. Then, the FMM pattern 225 is placed in an electrolytic bath having a second metal dissolved therein. The mandrel and the electrolytic bath are generally then biased for the second metal layer over the first metal layer.

The FMM pattern 225 includes a series of fine openings, which are useful, for example, to control evaporation of organic materials and/or metallic materials during OLED device formation. The series of fine openings generally block deposited materials from attaching to undesired areas of a substrate or on previously deposited layers, while allowing deposition on specified areas of a substrate or on previously deposited layers. The fine openings are generally any suitable size and shape, including but not limited to round, oval, or rectangular.

One or more lithography processes may then be used to optionally cover at least a portion of each FMM pattern 225 with a covering 235, as shown in FIG. 2D. In one aspect, the portion of the FMM pattern 225 is covered with a photoresist material, such as a dielectric material, to protect the FMM pattern 225 during subsequent processing. In one aspect, at least a portion of each FMM pattern 225 is covered with a covering 235 such that only the outermost edges of each FMM pattern 225 remain uncovered.

The FMM 230 is then combined with the CMM 205, as shown in FIG. 2E. Combining the CMM 205 and the FMM 230 generally includes placing the CMM 205 over the FMM 230, using and electroforming process to combine the exposed edges of each FMM pattern 225 with the CMM 205, and removing the coverings 235 and the distortion compensation master 215 to form a combined mask assembly 240.

In one aspect, the FMM 230 is combined with the CMM 205 using a further electroforming process to form plating, which joins the FMM 230 and the CMM 205 together for further processing. More particularly, the FMM patterns 225 are coupled to the CMM 205 to form the combined mask assembly 240. In one aspect, the FMM patterns 225 are welded to the CMM 205. In another aspect, the FMM patterns 225 are otherwise fastened to the CMM 205. The covering 235 over the portion of the FMM pattern 225 is then optionally removed from the front side of the combined mask assembly 240, and the distortion compensation master 215 is removed from the backside of the combined mask assembly 240, leaving the combined mask assembly 240 with the CMM 205 and the FMM patterns 225, as shown in FIG. 2F.

As described above, the combined mask assembly 240 is useful, for example, in vertical processing chambers and systems, such as those chambers and systems available from AKT, Inc., a division of Applied Materials, Inc., of Santa Clara Calif. When the combined mask assembly 240 is used in a vertical chamber and/or system, sagging occurs due to gravity. Since the distortion compensation master 215 was used, as described above and shown in FIGS. 2B-2D, the FMM patterns 225 are positioned such that the FMM patterns 225 near the center of the combined mask assembly 240 along the horizontal (x) axis are higher relative to the other FMM patterns 225 in their respective rows. Accordingly, when sagging occurs during vertical processing, the FMM patterns 225 are substantially centrally aligned within the windows 210 of the CMM 205, as shown in FIG. 2G.

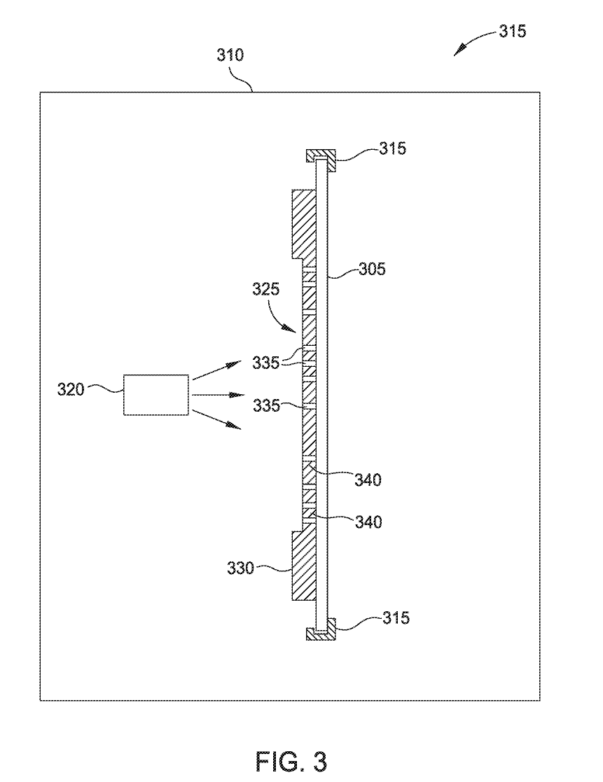

FIG. 3 schematically illustrates one aspect of an apparatus 300 for forming an OLED device on a substrate 305. The apparatus 300 includes a deposition chamber 310 where the substrate 305 is supported in a substantially vertical orientation. The substrate 305 may be supported by a carrier 315 adjacent to a deposition source 320. An FMM 325 is brought into contact with the substrate 305, and is positioned between the deposition source 320 and the substrate 305. The FMM 325 may be any one of the fine metal masks described herein. The FMM 325 may be tensioned and coupled to a frame 330 by fasteners (not shown), welding or other suitable joining method. The deposition source 320 may be an organic material that is evaporated onto precise areas of the substrate 305, in one aspect. The organic material is deposited through fine openings 335 formed in the FMM 325 between borders 340 according to formation methods as described herein. The FMMs described herein may comprise a single sheet having a pattern or multiple patterns of fine openings 335. Alternatively, the FMMs as described herein may be a series of sheets having a pattern or multiple patterns of fine openings 335 formed therein that are tensioned and coupled to the frame 330 in order to accommodate substrates of varying sizes.

The present disclosure provides a combined mask assembly that makes full contact with the device for manufacturing and which is well-aligned for vertical processing due to tapering and masking for gravity compensation. The combined metal mask disclosed herein may be used to form sub-pixel areas of an OLED device with high accuracy. Because of the high accuracy and alignment compensation for vertical processing, the combined mask assembly is useful for forming display devices, such as mobile phones, because the combined mask assembly for forming the OLEDs can be well-aligned with a glass substrate having a plurality of patterns, such as electrical circuits, thereon.

While the foregoing is directed to aspects of the present disclosure, other and further aspects of the disclosure may be devised without departing from the basic scope thereof, and the scope thereof is determined by the claims that follow.

What is claimed is:

1. A mask assembly, comprising:
a common metal mask having at least one window therethrough; and
a fine metal mask being disposed within the at least one window.

2. The mask assembly of claim 1, wherein the fine metal mask is not centered within the at least one window.

3. The mask assembly of claim 1, wherein the fine metal mask is positioned above center within the at least one window.

4. The mask assembly of claim 1, wherein the fine metal mask is positioned below center within the at least one window.

5. The mask assembly of claim 1, wherein the common metal mask is coupled to a frame.

6. A mask assembly, comprising:
a common metal mask portion having a plurality of windows formed therethrough; and
a plurality of fine metal mask portions disposed within the plurality of windows of the common metal mask portion.

7. The mask assembly of claim 6, wherein positions of each of the plurality of fine metal mask portions are located higher at or near a center of the common metal mask portion and decreasingly lower near an edge of the common metal mask portion.

8. The mask assembly of claim 6, wherein vertical positions of each of the plurality of fine metal mask portions are tapered from the center to an edge of the common metal mask portion.

9. The mask assembly of claim 6, wherein the common metal mask portion is coupled to a frame.

10. The mask assembly of claim 9, wherein the common metal mask portion is welded to the frame.

11. The mask assembly of claim 6, wherein each of the plurality of fine metal mask portions is coupled to the common metal mask portion with electroformed plating.

12. The mask assembly of claim 6, wherein each of the plurality of fine metal mask portions is welded to the common metal mask portion.

13. A method of manufacturing a mask assembly, comprising:
manufacturing a common metal mask having a plurality of windows therein;
forming a fine metal mask, comprising:
forming a distortion compensation master having a plurality of distortion compensation windows formed through the distortion compensation master, vertical positions of the distortion compensation windows being located higher at or near a center of the distortion compensation master and decreasingly lower near an edge of the distortion compensation master; and
forming a fine metal mask pattern within each of the distortion compensation windows; and
combining the common metal mask and the fine metal mask such that the fine metal mask patterns are disposed in the windows of the common metal mask.

14. The method of claim 13, wherein forming the fine metal mask comprises an electroforming process.

15. The method of claim 13, further comprising:
coupling the common metal mask to a frame, the frame comprising a sturdy metal material.

16. The method of claim 15, wherein the common metal mask is coupled to the frame under tension.

17. The method of claim 13, wherein the distortion compensation master is manufactured from glass.

18. The method of claim 13, further comprising:
removing the distortion compensation master.

19. The method of claim 13, further comprising:
forming a protective covering over at least a portion of the fine metal mask pattern in each of the distortion compensation windows, the protective covering comprising photoresist.

20. The method of claim 19, further comprising:
removing the protective covering.
